(19) United States
(12) Patent Application Publication
(10) Pub. No.: US 2026/0231706 A1
(43) Pub. Date: Aug. 6, 2026

(54) PLASMA ETCHING METHOD

(71) Applicant: AJOU UNIVERSITY INDUSTRY-ACADEMIC COOPERATION FOUNDATION, Suwon-si, Gyeonggi-do (KR)

(72) Inventors: Chang Koo KIM, Seoul (KR); Sang Hyun YOU, Suwon-si (KR); Eun Jae SUN, Gwangju-si (KR)

(73) Assignee: AJOU UNIVERSITY INDUSTRY-ACADEMIC COOPERATION FOUNDATION, Suwon-si, Gyeonggi-do (KR)

(21) Appl. No.: 19/154,086

(22) PCT Filed: Nov. 6, 2023
(86) PCT No.: PCT/KR2023/017626

§ 371 Date: Aug. 6, 2025

(30) Foreign Application Priority Data
Mar. 7, 2023 (KR) 10-2023-0030171

(51) Int. Cl. H10P 50/28; H01J 37/32

(52) U.S. Cl. CPC H10P 50/283; H01J 37/32449; H01J 2237/3341

(57) ABSTRACT

A plasma etching method is disclosed. The plasma etching method includes a first step of vaporizing liquid heptafluoroisopropyl methyl ether (HFE-347mmy); a second step of supplying a discharge gas containing the vaporized HFE-347mmy, oxygen gas and argon gas to a plasma chamber in which an etching target may be disposed; and a third step of discharging the discharge gas to generate plasma, and etching the etching target using the generated plasma.

### FIELD

The present disclosure relates to a plasma etching method, and more specifically, to a plasma etching method using heptafluoroisopropyl methyl ether (HFE-347mmy) having a low global warming potential as a discharge gas.

### DESCRIPTION OF RELATED ART

As the integration density of the semiconductor device increases, the operating temperature of the device increases. This lowers the stability of a Si-based semiconductor device. The band gap of Si is small at 1.1 eV, and thus, when a temperature is increased, the electrical energy barrier thereof is lowered such that leakage current is generated. Thus, Si is not suitable for use in a high temperature environment.

To solve this problem, silicon carbide (SiC) is attracting attention. SiC has a band gap of 2.4 to 3.3 eV, which is greater than that of Si, and thus has a high electrical energy barrier, and thus may be used even in a high-temperature environment. In addition, since the Si—C binding energy is strong, physical and chemical stability is high. Due to these characteristics, SiC may be used as a material for a semiconductor device in a power semiconductor microelectromechanical system (MEMS), automobiles, electrical industries, etc.

In the related art, plasma generated using SF₆, CF₄, CHF₃, NF₃, etc. as a discharge gas was used for etching the silicon carbide (SiC). However, SF₆, CF₄, CHF₃, NF₃, etc. as a discharge gas has a disadvantage in that SF₆, CF₄, CHF₃, NF₃, etc. has a high Global Warming Potential (GWP), which adversely affects global warming. Various schemes such as process optimization, exhaust gas decomposition, separation, and collection are being attempted to reduce process gas emissions. However, these schemes use high GWP gas and thus have a fundamental limitation.

Therefore, in order to solve the fundamental problem, it is necessary to develop a plasma etching process using a substitute substance having a low GWP.

### DISCLOSURE

### Technical Purposes

One purpose of the present disclosure is to provide a plasma etching method using heptafluoroisopropyl methyl ether (HFE-347mmy) having a low global warming potential and excellent etching performance as a discharge gas.

### Technical Solutions

One aspect of the present disclosure provides a plasma etching method comprising: a first step of vaporizing liquid heptafluoroisopropyl methyl ether (HFE-347mmy); a second step of supplying a discharge gas containing the vaporized HFE-347mmy, oxygen gas and argon gas to a plasma chamber in which an etching target may be disposed; and a third step of discharging the discharge gas to generate plasma, and etching the etching target using the generated plasma.

In one embodiment of the plasma etching method, in order to provide the vaporized HFE-347mmy to the plasma chamber, a first container containing the liquid HFE-347mmy may be heated to a first temperature equal to or greater than a boiling point of HFE-347mmy, and a first connection pipe connecting the first container and the plasma chamber may be heated to a second temperature higher than the first temperature.

In one embodiment of the plasma etching method, a ratio of an HFE-347mmy flow rate to a sum of HFE-347mmy flow rate and an oxygen gas flow rate in the discharge gas may be in a range of 10% to 50%.

In one embodiment of the plasma etching method, a ratio of the sum of HFE-347mmy flow rate and the oxygen gas flow rate and an argon gas flow rate may be in a range of 1:1 to 3:1.

In one embodiment of the plasma etching method, a source power of 400 to 700W may be applied to a plasma source coupled to the plasma chamber to generate the plasma of the discharge gas during the third step.

In one embodiment of the plasma etching method, a bias voltage of-700 V to-400 V may be applied to a substrate supporting the etching target thereon in the plasma chamber during the third step.

In one embodiment of the plasma etching method, the etching target may be silicon carbide (SiC).

### Technical Effects

According to the present disclosure, the mixed gas of the heptafluoroisopropyl methyl ether (HFE-347mmy), oxygen gas, and argon gas from which the plasma is generated may replace the etching gas such as SF₆, CF₄, CHF₃, NF₃ and the like having a high global warming potential, such that a semiconductor manufacturing process including the etching method of the present disclosure is environmentally friendly compared to a semiconductor manufacturing process using the etching gas having a high global warming potential which has been used in the prior art.

In addition, according to the present disclosure, the mixed gas of heptafluoroisopropyl methyl ether (HFE-347mmy), oxygen gas, and argon gas is used as the discharge gas and the ratio of the flow rates thereof is appropriately adjusted, such that the etch rate of the etching target may be improved and the roughness of the surface of the etching target subjected to the plasma etching may be minimized.

### BRIEF DESCRIPTION OF DRAWINGS

FIG. 1 is a schematic diagram of a plasma etching apparatus capable of performing a plasma etching method according to an embodiment of the present disclosure.

FIG. 2 is a graph illustrating a change in an etch rate of silicon carbide (SiC) based on a change in a ratio of an HFE-347mmy flow rate/an O₂ flow rate/an Ar flow rate in plasma etching performed under a condition described in Table 2.

FIG. 3 shows peak intensities of CF₂, F, and O radicals based on a change in a ratio of an HFE-347mmy flow rate/an O₂ flow rate/an Ar flow rate.

FIG. 4 is a graph showing a change in an etch rate of silicon carbide (SiC) based on various source power in a plasma etching performed under a condition shown in Table 3.

FIG. 5 is a graph illustrating a F-radical peak intensity of each of HFE-347mmy plasma and SF₆ plasma based on a change in a source power in each of HFE-347mmy/O₂/Ar discharge gas and SF₆/O₂/Ar discharge gas.

FIG. 6 is a graph showing a change in an etch rate of silicon carbide (SiC) based on various bias voltages in a plasma etching performed under a condition described in Table 4.

FIG. 7 is a graph illustrating a F radical peak intensity of each of HFE-347mmy plasma and SF₆ plasma based on a bias voltage change in each of HFE-347mmy/O₂/Ar discharge gas and SF₆/O₂/Ar discharge gas.

FIG. 8 is an image showing a surface roughness of silicon carbide (SiC) after etching based on various bias voltages in a plasma etching performed under a condition described in Table 4.

FIG. 9 shows the roughness of the SiC surface etched in each of HFE-347mmy/O₂/Ar discharge gas and SF₆/O₂/Ar discharge gas.

### DETAILED DESCRIPTIONS

Hereinafter, an embodiment of the present disclosure will be described in detail with reference to the accompanying drawings. The present disclosure may be variously modified and may take many forms. Thus, specific embodiments will be illustrated in the drawings and described in detail herein. However, the specific embodiments are not intended to limit the present disclosure thereto. It should be understood that any changes, equivalents thereto, or substitutes therewith are included in the scope and spirit of the present disclosure. In describing the drawing, similar reference numerals are used for similar components.

The terminology used herein is for the purpose of describing particular embodiments only and is not intends to be limiting of the present disclosure. As used herein, the singular forms “a” and “an” are intends to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or greater other features, integers, operations, elements, components, and/or portions thereof.

Unless otherwise defined, all terms including technical and scientific terms used herein have the same meaning as commonly understood by one of the ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

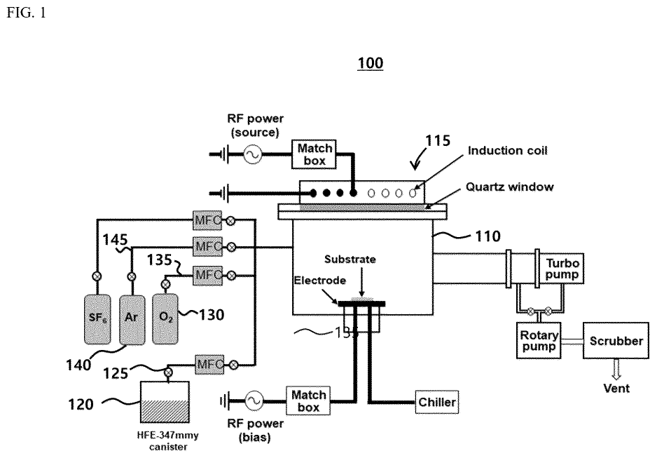

FIG. 1 is a schematic diagram of a plasma etching apparatus capable of performing a plasma etching method according to an embodiment of the present disclosure.

Referring to FIG. 1, a plasma etching method according to an embodiment of the present disclosure may include plasma-etching an etching target using a discharge gas containing heptafluoroisopropyl methyl ether (HFE-347mmy), an oxygen gas, and an argon gas in a plasma chamber in which the etching target is disposed.

The etching target is not particularly limited, but may be silicon carbide, silicon oxide, silicon nitride, or the like, which are generally used as a base material of a semiconductor device. Preferably, the etching target may be silicon carbide (SiC).

HFE-347mmy is known to have the physical properties of a following Table 1, and has a boiling point of about 29° C. and thus exists in a liquid state at room temperature, and has a GWP of 353, which is significantly lower than that of each of conventional PFC compounds. Therefore, the etching method according to the present disclosure is environmentally friendly because it has less adverse effects on global warming than plasma etching using conventional PFC compounds.

TABLE 1

| | |
|---|---|
| Chemical | The same as FIG. 10 |
| Structure | |
| Chemical name | (Heptafluoroisopropyl methyl ether) |
| | (HFE-347mmy) |
| Molecular | C₄H₃F₇O |
| formula | |
| Molecular | 200 |
| weight (M.W.) | |
| (g/mol) | |
| Boiling Point | 29 |
| (° C.) | |
| Global Warming | 353 |
| Potential (GWP) | |

Referring back to FIG. 1, the plasma etching method according to an embodiment of the present disclosure may be performed using a plasma etching apparatus shown in FIG. 1. In an embodiment, a plasma etching apparatus 100 may include a plasma chamber 110, a first container 120, a second container 130, and a third container 140. The plasma chamber 110 may be coupled to a plasma source 115, and may have a discharge space for containing an etching target (a wafer) therein. The discharge space may receive a discharge gas from the first to third containers 120, 130, and 140, and the plasma source 115 may generate plasma by applying a discharge voltage to the discharge gas.

The first to third containers 120, 130, and 140 may be connected to the plasma chamber 110 via first to third connection pipes 125, 135, and 145. The liquid HFE-347mmy may be contained in the first container 120, the oxygen gas may be contained in the second container 130, and the argon gas may be contained in the third container 140.

Heptafluoroisopropyl methyl ether (HFE-347mmy) may be contained in the first container 120. HFE-347mmy has a boiling point of about 29° C. in a liquid state at room temperature. Thus, in order to uniformly introduce the liquid HFE-347mmy into the plasma chamber 110, the liquid HFE-347mmy may be vaporized and then provided to the discharge space of the plasma chamber 110. In an embodiment, the vaporization of HFE-347mmy may be performed by heating the first container 120 containing the liquid HFE-347mmy therein and the first connection pipe 125 connecting the first container 120 and the plasma chamber 110 to each other to a temperature equal to or higher than the boiling point of HFE-347mmy. For example, in order to prevent a droplet from being splashed, the first container 120 may be heated to a temperature of about 50 to 80° C., and the first connection pipe 125 may be heated to a temperature of about 85 to 140° C.

The heating of the first container 120 and the first connection pipe 125 may be performed by an additional external device, and may be heated using, for example, a heating jacket. However, the present disclosure is not necessarily limited thereto. Any device capable of heating the container and the connection pipe may be used.

A mass flow controller may be additionally installed at an outlet of the first connection pipe 125. The mass flow controller may provide a constant flow rate of the vaporized HFE-347mmy to the discharge space of the plasma chamber 110.

The oxygen gas contained in the second container 130 and the argon gas contained in the third container 140 may be provided to the discharge space of the plasma chamber 110 via the second connection pipe 135 and the third connection pipe 145 different from the first connection pipe 125, respectively.

In accordance with the present disclosure, the oxygen gas and the argon gas together with the vaporized HFE-347mmy may be supplied into the plasma chamber.

In an embodiment, when the etching target is silicon carbide (SiC), a ratio of HFE-347mmy flow rate to a sum of HFE-347mmy flow rate and the oxygen gas flow rate in the discharge gas may be in a range of about 10% to 50%. When the ratio of HFE-347mmy flow rate to the sum of HFE-347mmy flow rate and the oxygen gas flow rate in the discharge gas is within the above range, the etch rate of silicon carbide may be improved. In addition, when the ratio of HFE-347mmy flow rate to the sum of HFE-347mmy flow rate and the oxygen gas flow rate is within the above range, an amount of F radicals as an etchant of SiC is increased, and at the same time, CF₂ radicals constituting the polymer are present in an appropriate amount to form a fluorocarbon thin film, thereby minimizing a roughness of the plasma-etched SiC surface.

When the ratio of the flow rate of HFE-347mmy to the sum of HFE-347mmy flow rate and the oxygen gas flow rate is smaller than 10%, an etching rate of the etching target may be excessively low. When the ratio of the flow rate of HFE-347mmy to the sum of HFE-347mmy flow rate and the oxygen gas flow rate is greater than 50%, an etch rate of SiC may be significantly lowered due to an increase in the radical CF₂ as a radical constituting a polymer, and a decrease in the radical O as a radical removing the polymer.

For example, when the etching target is silicon carbide (SiC), the ratio of HFE-347mmy flow rate to the sum of HFE-347mmy flow rate and the oxygen gas flow rate in the discharge gas may be about in a range of 10% to 50%, about 20% to 40%, or about 30% to 40%. Most preferably, the ratio of HFE-347mmy flow rate to the sum of HFE-347mmy flow rate and the oxygen gas flow rate in the discharge gas may be about 30%.

In an embodiment, a ratio of the sum of HFE-347mmy flow rate and the oxygen gas flow rate and the flow rate of the argon gas in the discharge gas may be within a range of about 1:1 to about 3:1. For example, the ratio of the sum of HFE-347mmy flow rate and the oxygen gas flow rate and the flow rate of the argon gas may be about 2:1.

When the ratio of the sum of HFE-347mmy flow rate and the oxygen gas flow rate and the flow rate of the argon gas is within the above range, the etch rate of silicon carbide (SiC) may be improved and the roughness of the plasma-etched SiC surface may be minimized.

In the plasma etching method according to an embodiment of the present disclosure, source power applied to the plasma source 115 to generate plasma of the discharge gas may be about 400W or greater. When the source power is lower than 400W, there may be a problem in that the etching rate of the etching target is significantly low. Further, in order to reduce power consumption, the source power applied to the plasma source 115 may be in a range of about 400W inclusive to 700W inclusive.

In addition, in the plasma etching method according to an embodiment of the present disclosure, a bias voltage applied to a substrate supporting an etching target thereon in the plasma chamber may be a voltage of about-400V to-700V. When the bias voltage is lower than-400V, an etch rate of the etching target may be excessively low. When the bias voltage is greater than-700V, an additional improvement in the etch rate may be hardly achieved, and only the surface roughness may be increased.

According to the plasma etching method of the present disclosure, the plasma etching process is performed using a mixture gas of HFE-347mmy which has a Global Warming Potential (GWP) significantly lower than that of the conventional PFC gas, the oxygen gas, and the argon (Ar) gas as the discharge gas, the discharge of greenhouse gas may be significantly reduced compared to the plasma etching process using the conventional PFC gas, and the plasma etching process may be performed to achieve excellent etching performance of an etching target such as silicon carbide, silicon nitride, silicon oxide, or the like.

In addition, according to the present disclosure, when the mixed gas of heptafluoroisopropyl methyl ether (HFE-347mmy), the oxygen gas, and the argon gas is used as the discharge gas and the ratio of the flow rates of the heptafluoroisopropyl methyl ether (HFE-347mmy), the oxygen gas, and the argon gas is appropriately adjusted, an etch rate of an etching target may be improved and roughness of a surface of the etching target subjected to the plasma etching may be minimized. In particular, according to the plasma etching process of the present disclosure, the ratio of HFE-347mmy flow rate, the oxygen gas flow rate, and the argon gas flow rate in the discharge gas may be appropriately adjusted to improve the etch rate of silicon carbide (SiC) and minimize the roughness of the plasma-etched surface of the SiC.

Hereinafter, more specific examples and experimental examples will be described. However, the following examples are only some implementations of the present disclosure, and the scope of the present disclosure is not limited to the following examples.

### EXAMPLES

Plasma etching was performed on SiC under various conditions using a mixed gas of HFE-347mmy, oxygen, and argon as the discharge gas. In this regard, the discharge gas was provided to the etching chamber at a flow rate of 15 sccm. When the liquid HFE-347mmy was vaporized and supplied to the plasma chamber, the first container containing the liquid HFE-347mmy was heated to 75° C., and the first connection pipe connecting the first container and the plasma chamber to each other was heated to 135° C.

### Experimental Example 1

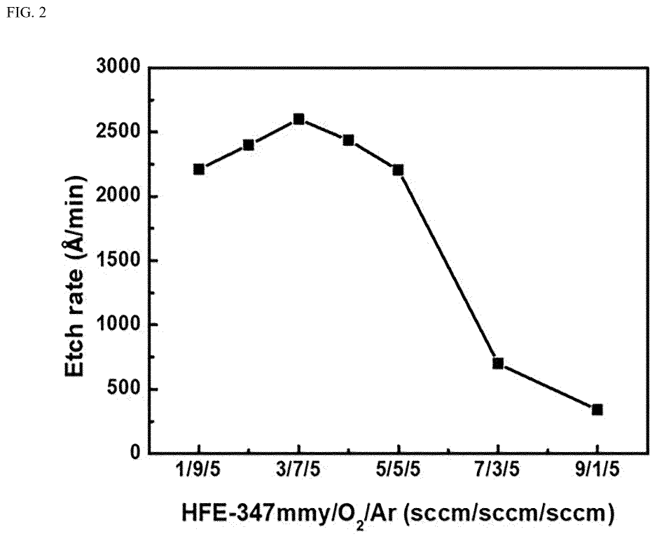

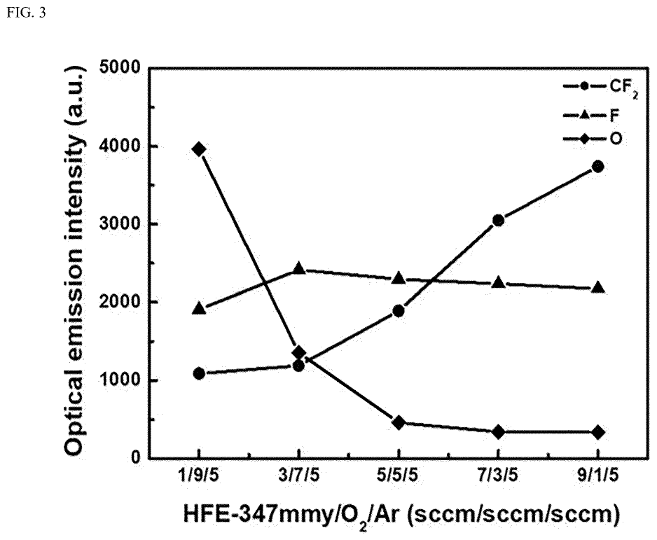

FIG. 2 is a graph showing a change in the etch rate of silicon carbide (SiC) based on a change in the ratio of HFE-347mmy flow rate/the O₂ flow rate/the Ar flow rate in plasma etching performed under a condition shown in the following Table 2. In the plasma etching process, a polyimide tape was attached to a portion of a specimen and then the specimen was etched such that the portion thereof to which the tape was attached was not etched. After the process was completed, the etch rate was measured based on a measuring result of a size of a step between the etched and unetched portions.

TABLE 2

| | |
|---|---|
| Source power (W) | 500 |
| Bias voltage (V) | −500 |
| Discharge gas | HFE-347mmy/O₂/Ar |
| Flow rate (sccm) | HFE-347mmy flow rate/O₂ flow rate/Ar |
| | flow rate 1/9/5, 3/7/5, 5/5/5, 7/3/5, 9/1/5 |
| Pressure (mTorr) | 30 |
| Electrode temperature (° C.) | 15 |

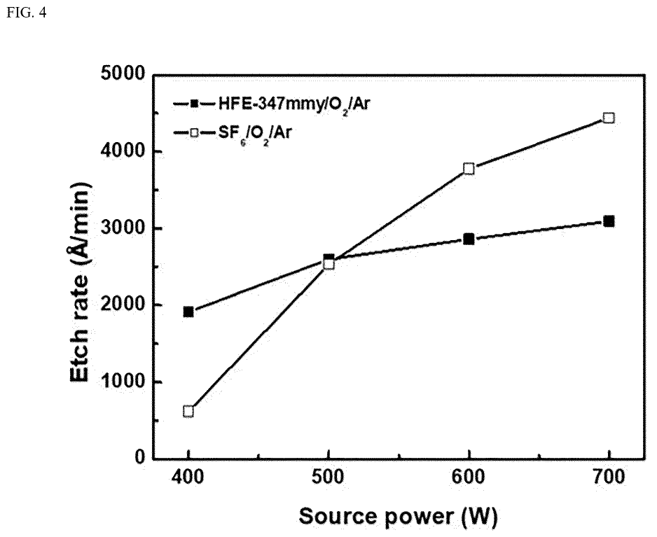

Referring to FIG. 2, as the ratio of HFE-347mmy flow rate and the O₂ flow rate changes from 1:9 to 3:7, the etch rate of SiC increases. The etch rate becomes maximum when the ratio is 3:7. As the ratio of HFE-347mmy flow rate and the O₂ flow rate changes from 3:7 to 5:5, the etch rate decreases again. The etch rate decreases significantly in a range where the ratio of HFE-347mmy flow rate and the O₂ flow rate changes from 5:5 to 9:1. FIG. 3 shows peak intensities of CF₂, F, and O radicals based on a change in a ratio of a HFE-347mmy flow rate/an O₂ flow rate/an Ar flow rate.

Referring to FIG. 3, a peak intensity of CF₂ radicals increases as the ratio of HFE-347mmy flow rate and the O₂ flow rate changes from 1:9 to 9:1. A peak intensity of O radicals decreases as the ratio of HFE-347mmy flow rate and the O₂ flow rate changes from 1:9 to 9:1. The peak intensity of the F radical increases as the ratio of HFE-347mmy flow rate and the O₂ flow rate changes from 1:9 to 3:7. The peak intensity of the F radical is the maximum when the ratio is 3:7. As HFE-347mmy flow rate increases such that the ratio of HFE-347mmy flow rate and the O₂ flow rate changes from 3:7 to 9:1, the peak intensity of the F radical decreases.

Referring to the results of FIGS. 2 and 3, it may be identified that when HFE-347mmy flow rate increases such that the ratio of HFE-347mmy flow rate and the O₂ flow rate changes from 1:9 to 3:7, the amount of the F radicals as the etchant of SiC increases, and thus the SiC etch rate also increases. Thereafter, when HFE-347mmy flow rate increases such that the ratio of HFE-347mmy flow rate and the 02 flow rate changes from 3:7 to 9:1, the amount of the CF₂ radicals constituting the polymer increases and the O radicals removing the polymer decreases, resulting in a decrease in the etch rate of SiC.

### Experimental Example 2

In the present disclosure, a plasma etching process was performed using the ratio of HFE-347mmy flow rate/O₂ flow rate/Ar flow rate of 3:7:5 which is a condition under which the SiC etch rate is the highest as the discharge gas. In Comparative Example, a plasma etching process was performed using a mixture gas of SF₆, oxygen, and argon as the discharge gas. Then, the SiC etch rates of the present disclosure and Comparative Example were compared with each other.

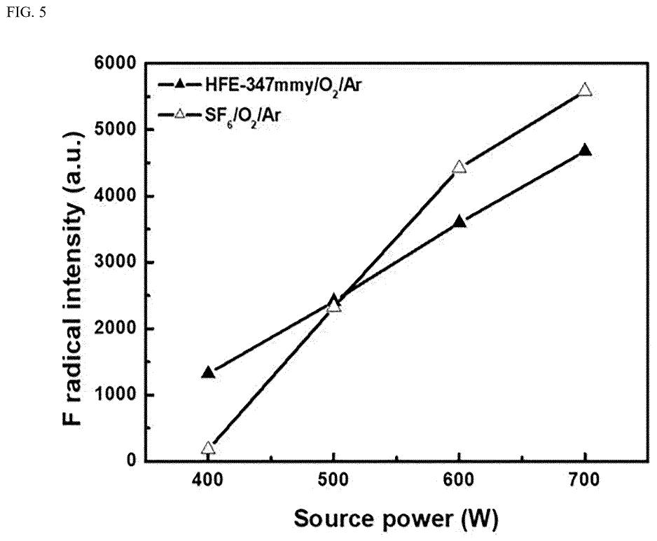

FIG. 4 is a graph showing a change in an etch rate of silicon carbide (SiC) based on various source powers in a plasma etching performed under a condition shown in Table 3 below.

TABLE 3

| | |
|---|---|
| Source power (W) | 400, 500, 600, 700 |
| Bias voltage (V) | −500 |
| Discharge gas | HFE-347mmy/O₂/Ar or SF₆/O₂/Ar |
| Flow rate (sccm) ratio | HFE-347mmy flow rate/O₂ flow rate/Ar |
| | flow rate or SF₆ flow rate/O₂ flow rate/Ar |
| | flow rate 3/7/5 |
| Pressure (mTorr) | 30 |
| Electrode temperature (° C.) | 15 |

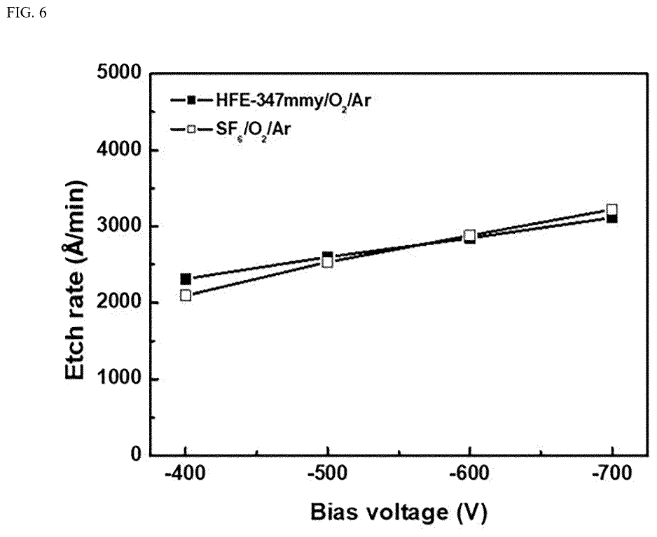

Referring to FIG. 4, it may be identified that as the source power increases, both HFE-347mmy plasma and the SF₆ plasma achieve an increase in the SiC etch rate. When the source power is 400 W, HFE-347mmy plasma achieves a higher SiC etch rate than that in the SF₆ plasma. When the source power is 500 W, HFE-347mmy plasma and the SF₆ plasma achieve similar etch rates. FIG. 5 is a graph illustrating a peak intensity of F radicals in each of HFE-347mmy plasma and the SF₆ plasma based on a change in source power in HFE-347mmy/O₂/Ar discharge gas and SF₆/O₂/Ar discharge gas.

Referring to FIG. 5, both HFE-347mmy plasma and the SF₆ plasma achieve an increase in the amount of the F radicals as the source power increases, because as the source power increases, dissociation increases, and thus the amount of the F radicals increases.

Specifically, in FIG. 5, when the source power is 400 W, the amount of the F radicals in HFE-347mmy plasma is greater than that in the SF₆ plasma. When the source power increases to 500 W, the amount of the F radical in HFE-347mmy plasma and that in the SF₆ plasma are similar to each other.

The SiC etch rate trend of each of HFE-347mmy plasma and the SF₆ plasma of FIG. 4 is similar to the F radical peak intensity trend of each of HFE-347mmy plasma and the SF₆ plasma of FIG. 5. This is a result indicating that the F radical acts as the etchant of silicon carbide (SiC).

### Experimental Example 3

FIG. 6 is a graph showing a change in an etch rate of silicon carbide (SiC) based on various bias voltages in a plasma etching performed under a condition shown in Table 4 below.

TABLE 4

| | |
|---|---|
| Source power (W) | 500 |
| Bias voltage (V) | −400, −500, −600, −700 |
| Discharge gas | HFE-347mmy/O₂/Ar or SF₆/O₂/Ar |
| Flow rate (sccm) ratio | HFE-347mmy flow rate/O₂ flow rate/Ar |
| | flow rate or SF₆ flow rate/O₂ flow rate/Ar |
| | flow rate 3/7/5 |
| Pressure (mTorr) | 30 |
| Electrode temperature (° C.) | 15 |

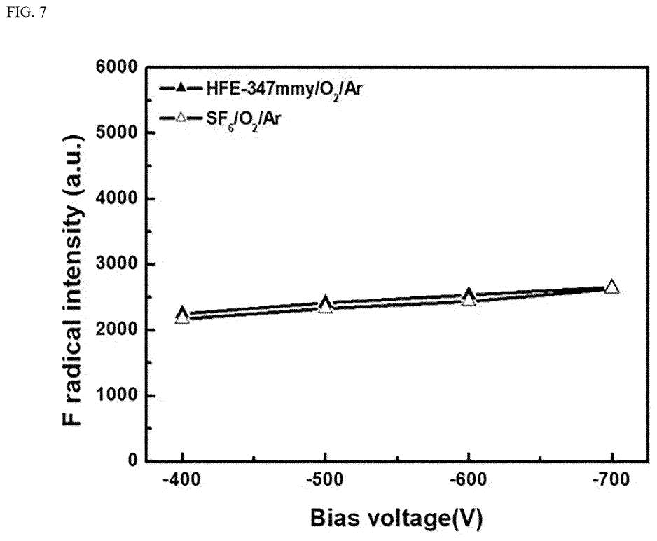

Referring to FIG. 6, it may be identified that the SiC etch rates of HFE-347mmy plasma and the SF₆ plasma are almost similar to each other in all bias voltages. Further, the SiC etch rate increases as the bias voltage increases. FIG. 7 is a graph illustrating the peak intensity of the F radicals in each of HFE-347mmy plasma and the SF₆ plasma based on a bias voltage change in each of HFE-347mmy/O₂/Ar discharge gas and the SF₆/O₂/Ar discharge gas.

Referring to FIG. 7, as the bias voltage increases, the peak intensity of the F radicals increases in both HFE-347mmy plasma and the SF₆ plasma, because as the bias voltage increases, a capacitive coupling effect increases, and thus the peak intensity of the F radicals increases.

Specifically, in FIG. 7, the peak intensities of the F radicals of HFE-347mmy plasma and the SF₆ plasma are substantially similar to each other under all bias voltages.

The SiC etch rate trend of each of HFE-347mmy plasma and the SF₆ plasma of FIG. 6 is similar to the F radical peak intensity trend of each of HFE-347mmy plasma and the SF₆ plasma of FIG. 7. This is a result indicating that the F radical acts as the etchant of silicon carbide (SiC).

### Experimental Example 4

Since the plasma-etched silicon carbide (SiC) directly contacts the channel of the high-power semiconductor device, the carrier mobility of the channel may vary greatly depending on the surface roughness of the etched SiC. Therefore, in order to suppress a problem caused by the high surface roughness, minimizing the roughness of the surface of silicon carbide (SiC) subjected to the plasma etching is an important factor.

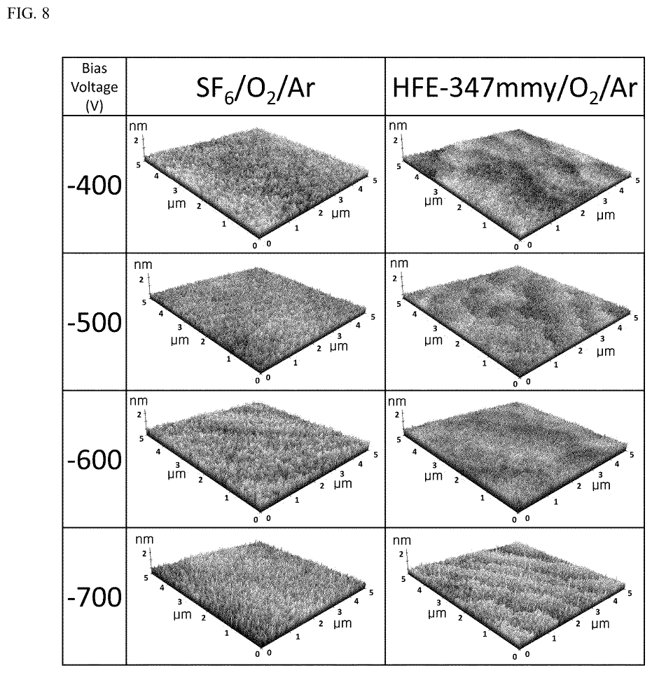

In order to identify this fact, an image of comparing the surface roughness of the silicon carbide (SiC) subjected to the various plasma etching processes performed using HFE-347mmy/O₂/Ar discharge gas and the SF₆/O₂/Ar discharge gas under various bias voltage conditions as described in Table 4 is shown in FIG. 8.

Referring to FIG. 8, it may be identified that as the bias voltage increases, both the SiC etched with HFE-347mmy plasma and the SiC etched with the SF₆ plasma have higher surface roughness. In addition, it may be identified that under all bias voltage conditions, the surface of the SiC etched with the SF₆ plasma has higher surface roughness than that of the surface of the SiC etched with HFE-347mmy plasma.

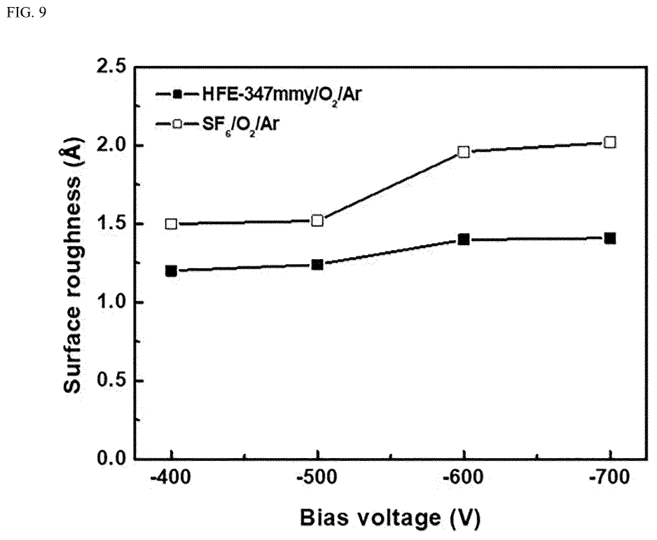

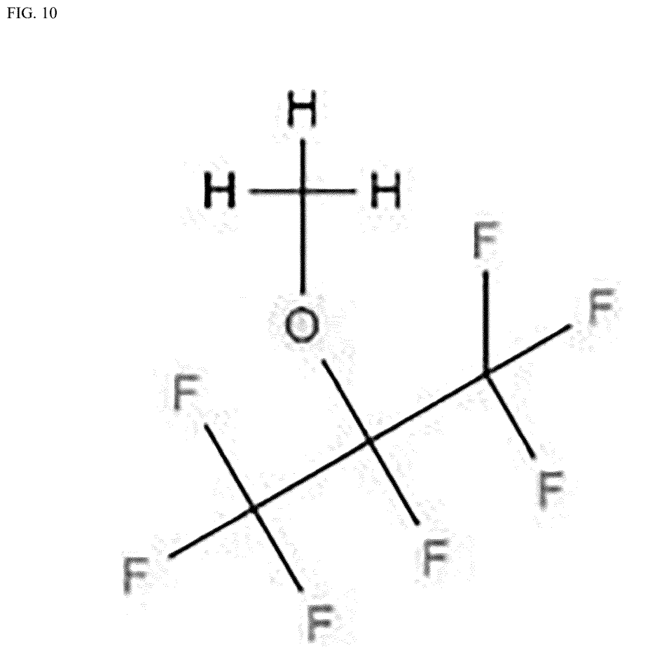

FIG. 9 shows the roughness of the SiC surface etched in each of HFE-347mmy/O₂/Ar discharge gas and SF₆/O₂/Ar discharge gas.

Referring to FIG. 9, as the bias voltage increases, the surface roughness of each of the SiC etched with HFE-347mmy plasma and the SiC etched with the SF₆ plasma increases. This is because as the bias voltage increases, the ion energy increases, and thus the energy of ions incident on the SiC surface increases.

Specifically, the surface roughness of the SiC etched with the SF₆ plasma is greater than the surface roughness of the SiC etched with HFE-347mmy plasma under all bias voltage conditions. HFE-347mmy plasma is converted into a fluorocarbon thin film on the SiC surface due to the presence of CF₂ radicals constituting the fluorocarbon thin film, while SF₆ plasma is free of the CF₂ radicals so that the fluorocarbon thin film is not formed. The carbon fluoride thin film may act as a hindrance to the etching during the SiC etching. Accordingly, ion energy incident on the SiC surface is reduced due to the fluorocarbon thin film formed on the SiC surface during the etching with HFE-347mmy plasma, thereby minimizing the surface roughness compared to that in the SiC surface etched with the SF₆ plasma.

Although the present disclosure has been described above with reference to the preferred embodiments of the present disclosure, those skilled in the art will understand that the present disclosure may be variously modified and changed within the scope not departing from the spirit and scope of the present disclosure described in the following patent claims.

### REFERENCE NUMERALS

100: Etching apparatus
110: Plasma chamber
115: Plasma source
120: First container
125: First Connection Pipe
130: Second container
135: Second Connection Pipe
140: Third container
145: Third Connection Pipe

1. A plasma etching method comprising:
a first step of vaporizing liquid heptafluoroisopropyl methyl ether (HFE-347mmy);
a second step of supplying a discharge gas containing the vaporized HFE-347mmy, oxygen gas and argon gas to a plasma chamber in which an etching target is disposed; and
a third step of discharging the discharge gas to generate plasma, and etching the etching target using the generated plasma.

2. The plasma etching method of claim 1, wherein in order to provide the vaporized HFE-347mmy to the plasma chamber,
a first container containing the liquid HFE-347mmy is heated to a first temperature equal to or greater than a boiling point of HFE-347mmy, and a first connection pipe connecting the first container and the plasma chamber is heated to a second temperature higher than the first temperature.

3. The plasma etching method of claim 1, wherein a ratio of a HFE-347mmy flow rate to a sum of HFE-347mmy flow rate and an oxygen gas flow rate in the discharge gas is in a range of 10% to 50%.

4. The plasma etching method of claim 3, wherein a ratio of the sum of HFE-347mmy flow rate and the oxygen gas flow rate and an argon gas flow rate is in a range of 1:1 to 3:1.

5. The plasma etching method of claim 1, wherein a source power of 400 to 700W is applied to a plasma source coupled to the plasma chamber to generate the plasma of the discharge gas during the third step.

6. The plasma etching method of claim 1, wherein a bias voltage of −700 V to −400 V is applied to a substrate supporting the etching target thereon in the plasma chamber during the third step.

7. The plasma etching method of claim 1, wherein the etching target is silicon carbide (SiC).
